(19) United States
(12) Patent Application Publication
(10) Pub. No.: US 2025/0123129 A1
(43) Pub. Date: Apr. 17, 2025

(54) SENSING DEVICE

(71) Applicant: Sitronix Technology Corporation, Hsinchu County (TW)

(72) Inventor: Sheng-Ying Lin, Hsinchu County (TW)

(21) Appl. No.: 18/523,981

(22) Filed: Nov. 30, 2023

(30) Foreign Application Priority Data
Oct. 16, 2023 (TW) 112139407

(51) Int. Cl. G01D 21/00; H03H 7/06

(52) U.S. Cl. CPC G01D 21/00; H03H 7/06

(57) ABSTRACT

The present application discloses a sensing device, in which obtaining a first filtered signal by a first filter element according to a sensing reference signal corresponding to a sensing signal and obtaining a second filtered signal by a second filter element according to an analog reference signal, and then a noise compensation signal is generated according to the first filtered signal and the second filtered signal. Hereby, an analog-front-end circuit will decrease a noise of the sensing signal by compensating the sensing signal after the sensing signal and the noise compensation signal are received.

### FIELD OF THE INVENTION

The present application related to an electronic devise, in particular to a sensing device, in which a noise of a sensing signal is decreased by compensating the sensing signal.

### BACKGROUND OF THE INVENTION

With the development of consumer electronic devices, consumer electronic devices will be equipped with a variety of sensing functions, such as touch sensing and proximity sensing. Generally, each of consumer electronic devices with touch sensing functions is adopted with a touch panel and a display panel for user touching a displayed screen image on the display panel to generate input signals to the consumer electronic devices. Therefore, the display panels to work with touch panels may include liquid crystal displays (LCDs), field emission displays (FEDs), plasma display panels (PDPs), electroluminescent displays (ELDs), electrophoretic displays (EPDs), and organic light-emitting devices (OLEDs). The touch panels allow the user to use touch methods such as fingers and pens to press it or contact it, so that the sensing device on the touch panel senses the user's touch position and combines the screen information to generate corresponding input information.

In the circuit design of sensing devices, most circuit components today use semiconductor components. With changes in manufacturing processes and even changes in materials, other circuit components in consumer electronic devices will cause the sensing device to withstand noise or even interference sensing results. For example, when a user operates a consumer electronic device with a touch device, a plurality of semiconductor switching elements connected between the display panel and the driving element perform switching actions. These switches are usually influenced by the difference between the voltage on the data line and the voltage output by the driver. Then charge sharing may occur between the switching elements, causing the display panel to generate noise to other circuit elements. Alternatively, when data transmission is performed according to the MIPI DSI standard between a system on chip (SoC) of a consumer electronic device and a display device, an idle period or a stop state of data transmission causes a data channel to stop for a period. This stop causes the display panel to generate power noise or noise associated with data transmission, thereby affecting the sensing devices on the consumer electronic devices.

To solve the above problems, the present application provides a sensing device. A noise compensation circuit is coupled to a sensing circuit and an analog-front-end (AFE) circuit. The noise compensation circuit generates a first filtered signal according to a sensing reference signal corresponding to a sensing signal of the sensing circuit, a second filtered signal according to an analog reference signal, and a noise compensation signal according to the first and second filtered signals. The AFE circuit may receive the sensing signa and the noise compensation signal, respectively, and compensates the sensing signal according to the noise compensation signal for reducing a noise of the sensing signal.

### SUMMARY OF THE INVENTION

An objective of the present application is to provide a sensing device, which comprises a noise compensation circuit for generating a noise compensation signal. The noise compensation signal is input to an analog-front-end (AFE) circuit along with a sensing signal. The AFE circuit compensates the sensing signal according to the noise compensation signal for reducing a noise of the sensing signal.

To achieve the above objective, the present application provides a sensing device, which comprises an AFE circuit, a sensing circuit, and a noise compensation circuit. The noise compensation circuit is coupled to the sensing circuit and the AFE circuit, respectively. The AFE circuit includes a first filtering element, a second filtering element, and an operation element. The first filtering element generates a first filtered signal according to a corresponding sensing reference signal of the sensing signal. The second filtering element generates a second filtered signal according to an analog reference signal. Thereby, the first filtered signal and the second filtered signal correspond to different cutoff frequencies. The operation element generates a noise compensation signal according to the first filtered signal and the second filtered signal. The AFE circuit compensates the sensing signal according to the noise compensation signal for reducing a noise of the sensing signal.

### BRIEF DESCRIPTION OF DRAWINGS

FIG. 1 shows a block diagram of the sensing device according to the present application;

FIG. 2 shows a schematic diagram of signal transmission of the sensing device according to the first embodiment of the present application;

FIG. 3A shows a schematic diagram of signal transmission of the sensing device according to the second embodiment of the present application;

FIG. 3B shows a schematic diagram of signal transmission of the sensing device according to the third embodiment of the present application;

FIG. 3C shows a schematic diagram of signal transmission of the sensing device according to the fourth embodiment of the present application;

FIG. 3D shows a schematic diagram of signal transmission of the sensing device according to the fifth embodiment of the present application;

FIG. 4A shows a schematic diagram of signal transmission of the sensing device according to the sixth embodiment of the present application;

FIG. 4B shows a first schematic diagram of the first bandpass filtering element according to the present application;

FIG. 4C shows a second schematic diagram of the first bandpass filtering element according to the present application;

FIG. 4D shows a third schematic diagram of the first bandpass filtering element according to the present application;

FIG. 5 shows a schematic diagram of signal transmission of the sensing device according to the seventh embodiment of the present application;

FIG. 6 shows a schematic diagram of signal transmission of the sensing device according to the eighth embodiment of the present application;

FIG. 7 shows a schematic diagram of signal transmission of the sensing device according to the ninth embodiment of the present application;

FIG. 8A shows a schematic diagram of signal transmission of the sensing device according to the tenth embodiment of the present application;

FIG. 8B shows a first schematic diagram of the bandpass filtering element according to the present application;

FIG. 8C shows a second schematic diagram of the bandpass filtering element according to the present application;

FIG. 9 shows a schematic diagram of signal transmission of the sensing device according to the eleventh embodiment of the present application;

FIG. 10 shows a schematic diagram of signal transmission of the sensing device according to the twelfth embodiment of the present application;

FIG. 11 shows a schematic diagram of signal transmission of the sensing device according to the thirteenth embodiment of the present application;

FIG. 12 shows a schematic diagram of signal transmission of the sensing device according to the fourteenth embodiment of the present application;

FIG. 13 shows a schematic diagram of signal transmission of the sensing device according to the fifteenth embodiment of the present application;

FIG. 14 shows a schematic diagram of signal transmission of the sensing device according to the sixteenth embodiment of the present application;

FIG. 15 shows a schematic diagram of signal transmission of the sensing device according to the seventeenth embodiment of the present application;

FIG. 16 shows a schematic diagram of signal transmission of the sensing device according to the eighteenth embodiment of the present application;

FIG. 17 shows a schematic diagram of signal transmission of the sensing device according to the nineteenth embodiment of the present application;

FIG. 18 shows a schematic diagram of signal transmission of the sensing device according to the twentieth embodiment of the present application; and

FIG. 19 shows a schematic diagram of signal transmission of the sensing device according to the twenty-first embodiment of the present application.

### DETAILED DESCRIPTION OF THE INVENTION

In order to make the structure and characteristics as well as the effectiveness of the present application to be further understood and recognized, the detailed description of the present application is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

To solve the noise problem in the signal processing process of a sensing device, the present application provides a sensing device, which generates a first filtered signal by a noise compensation circuit according to a corresponding sensing reference signal of a sensing signal of a sensing circuit and generates a second filtered signal according to an analog reference signal. According to the first filtered signal and the second filtered signal, a noise compensation signal is generated. Thereby, an analog-front-end (AFE) circuit of the sensing device may compensate the sensing signal according to the noise compensation signal and thus reducing the noise in the signal processing process.

In the following description, various embodiments of the present application are described using figures for describing the present application in detail. Nonetheless, the concepts of the present application may be embodied by various forms. Those embodiments are not used to limit the scope and range of the present application.

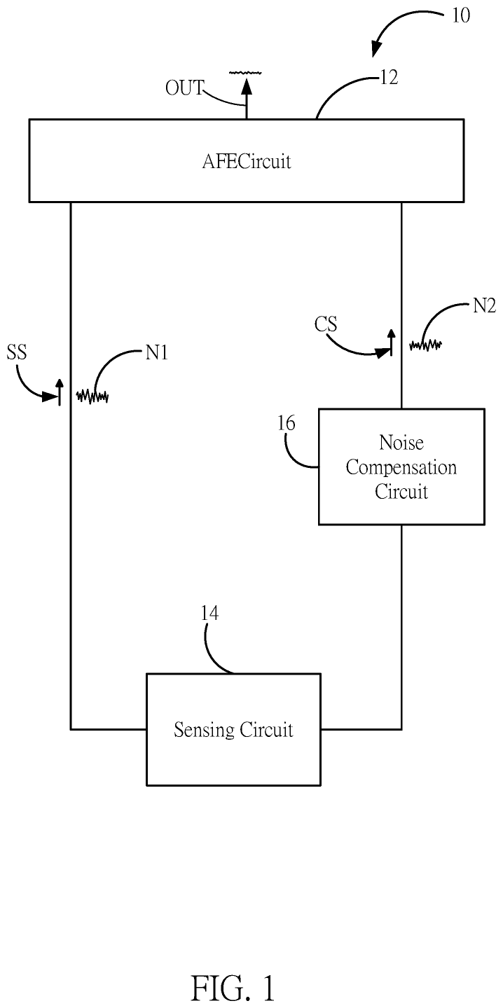

First, please refer to FIG. 1, which shows a block diagram of the sensing device according to the present application. As shown in the figure, a sensing device 10 according to the present embodiment comprises an AFE circuit 12, a sensing circuit 14, and a noise compensation circuit 16. The sensing circuit 14 and the noise compensation circuit 16 are both coupled to the AFE circuit 12. The noises compensation circuit 16 is further coupled to the sensing circuit 14. The sensing circuit 14 generates a sensing signal SS to the AFE circuit 12. The noise compensation circuit 16 generates a noise compensation signal CS to the AFE circuit 12. The sensing signal SS includes a first noise N1. The noise compensation signal CS includes a second noise N2. The AFE circuit 12 compensates the sensing signal SS according to the noise compensation signal CS and thus eliminating the first noise N1 in the sensing signal SS. In addition, an output signal OUT of the AFE circuit 12 is exhibited signal waveforms with less noise. The details will be described in the following.

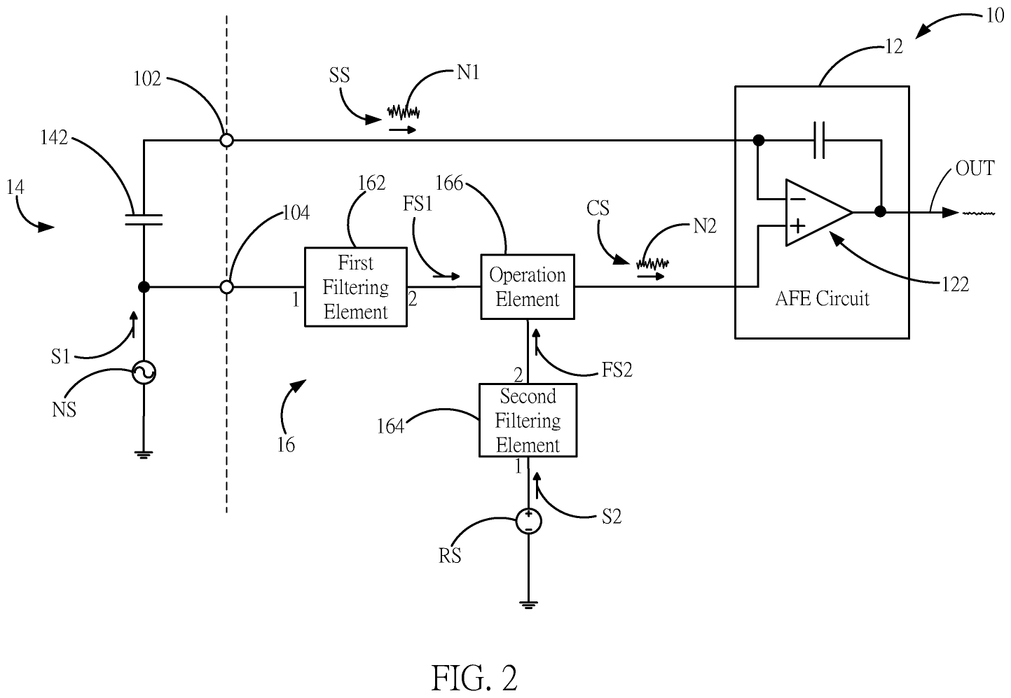

Please refer to FIG. 2, which shows a schematic diagram of signal transmission of the sensing device according to the first embodiment of the present application. As shown in the figure, the sensing circuit 14 according to the present embodiment includes a capacitive sensing device 142 corresponding to a sensing reference signal S1. The noise compensation circuit 16 according to the present embodiment includes a first filtering element 162, a second filtering element 164, and an operation element 166. The capacitive sensing device 142 is coupled to the AFE circuit 12 via a sensing terminal 102 of the sensing device 10. A first terminal of the first filtering element 162 is coupled to the capacitive sensing device 142 via a non-sensing terminal 104 of the sensing device 10 and receives the sensing reference signal S1. A second terminal of the first filtering element 162 is coupled to the operation element 166. A first terminal of the second filtering element 164 receives an analog reference signal S2. A second terminal of the second filtering element 164 is coupled to the operation element 166. According to an exemplary embodiment, the operation element 166 may be coupled to the second terminal of the first filtering element 162 and the second terminal of the second filtering element 164. The voltage of the analog reference signal S2 corresponds to the operating voltage of the AFE circuit 12. The sensing reference signal S1 further corresponds to the noise, for example, the noise from the display panel (not shown in the figure), received by the sensing device 10. The sensing device 10 may generate the corresponding noise compensation signal CS by using the noise compensation circuit 16, the first filtering element 162, and the second filtering element 164. The noise compensation signal CS is used for compensating the first noise N1 of the sensing signal SS received by the AFE circuit 12, maintaining the characteristics of the operating voltage of the AFE circuit 12, and improving the signal-to-noise ratio (SNR) of the sensing circuit 14.

Please refer to FIG. 2 again. The first filtering element 162 generates a first filtered signal FS1 according to the sensing reference signal S1. The second filtering element 164 generates a second filtered signal FS2 according to the analog reference signal S2. The operation element 166 generates the noise compensation signal CS according to the first filtered signal FS1 and the second filtered signal FS2. Since the cutoff frequencies of the first filtered signal FS1 and the second filtered signal FS2 are different, the noise compensation signal CS generated by the operation element 166 according to the first filtered signal FS1 and the second filtered signal FS2, likewise, corresponds to different cutoff frequencies. Thereby, the AFE circuit 12 may eliminate the noise of the sensing signal SS according to the noise compensation signal CS and the output signal OUT generated by the AFE circuit 12 contains less noise.

In addition, the sensing circuit 14 according to the present embodiment is further coupled to a first reference power source NS, which supplies the sensing reference signal S1 to the sensing circuit 14. Thereby the first terminal of the first filtering element 162 is coupled between the sensing circuit 14 and the first reference power source NS for acquiring the sensing reference signal S1 and generating the first filtered signal FS1. The noise compensation circuit 16 according to the present embodiment is further coupled to a second reference power source RS, which supplies the analog reference signal S2 to the noise compensation circuit 16. Thereby, the first terminal of the second filtering element 164 is coupled to the second reference power source RS for acquiring the analog reference signal S2 and generating the second filtered signal FS2. The first reference power source NS and the second reference power source RS are coupled to the ground, respectively. Moreover, for illustration, the AFE circuit 12 according to the present embodiment includes an amplifier circuit 122. Nonetheless, the present application is not limited to the embodiment. The AFE circuit 12 may be adjusted according to requirements. For example, the AFE circuit 12 may further include a modulation circuit for modulating the bandwidth or the duty cycle. The amplifier circuit 122 receives the sensing signal SS and the noise compensation signal CS. The first noise N1 of the sensing signal SS may compensate the second noise N2 of the noise compensation signal CS and thus reducing the first noise N1. Thereby, the waveform of the output signal OUT of the AFE circuit 12 may be smoother and hence reducing the proportion of noise in the overall signal. Consequently, the resent invention may improve the signal-to-noise ratio of the sensing signal SS.

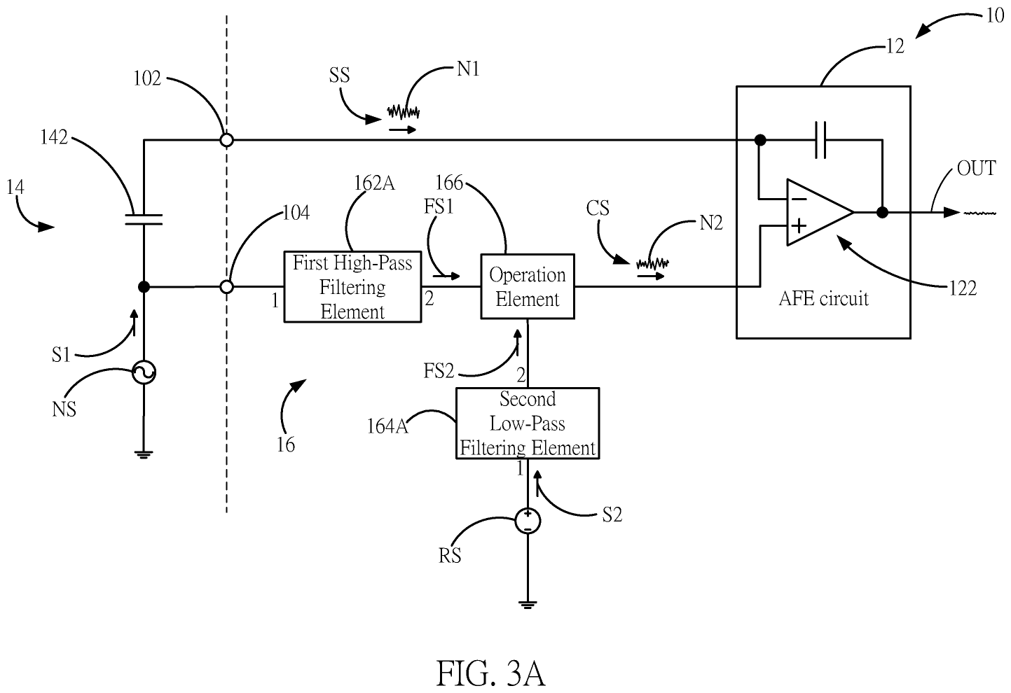

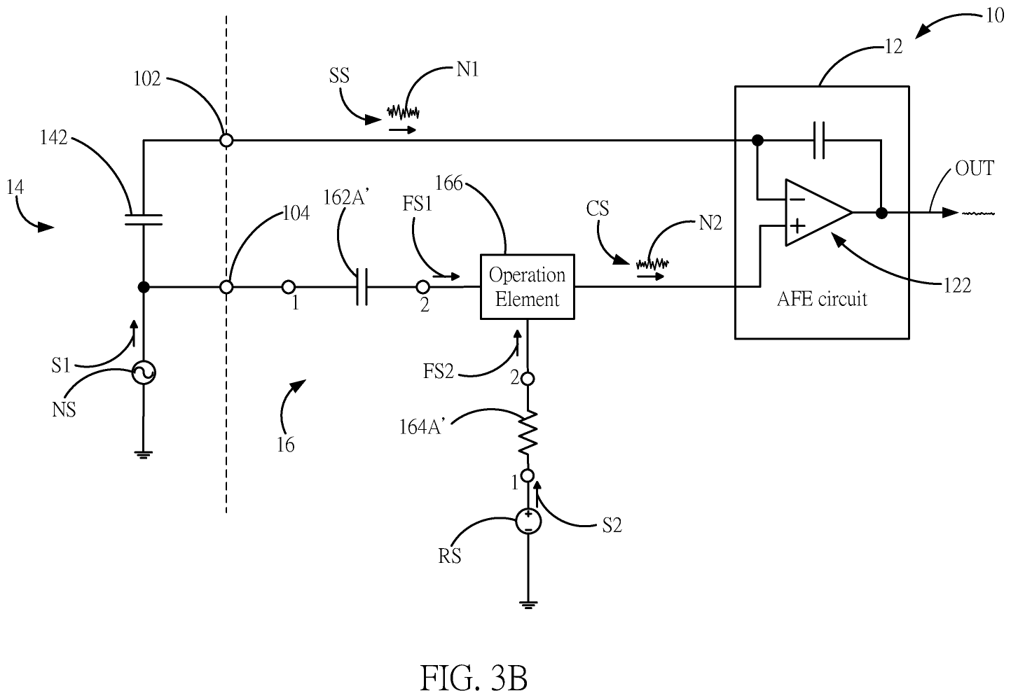

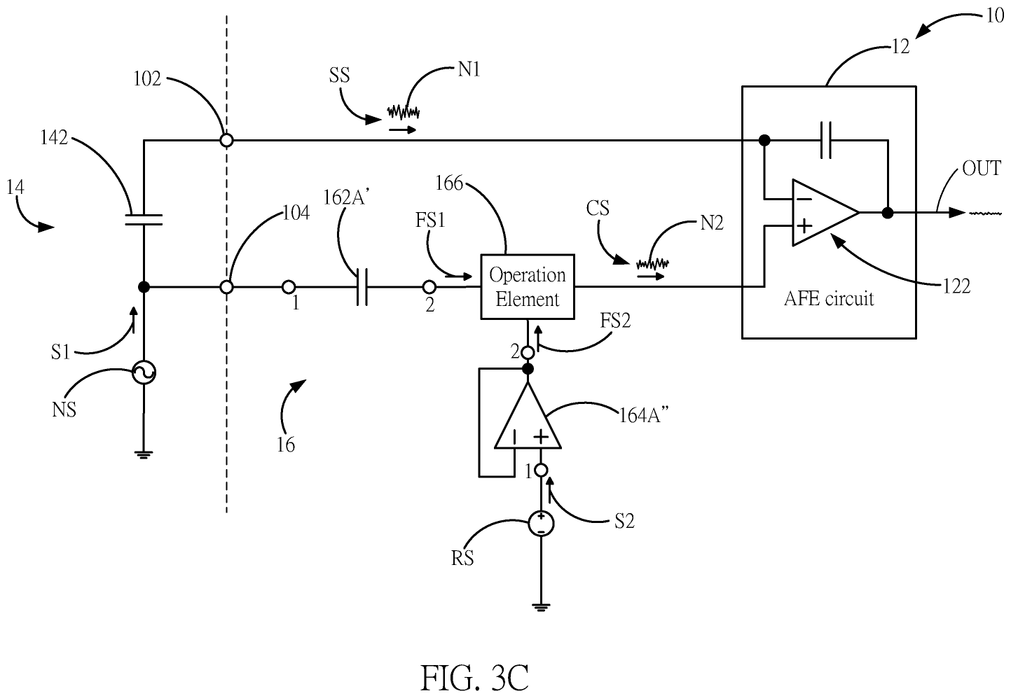

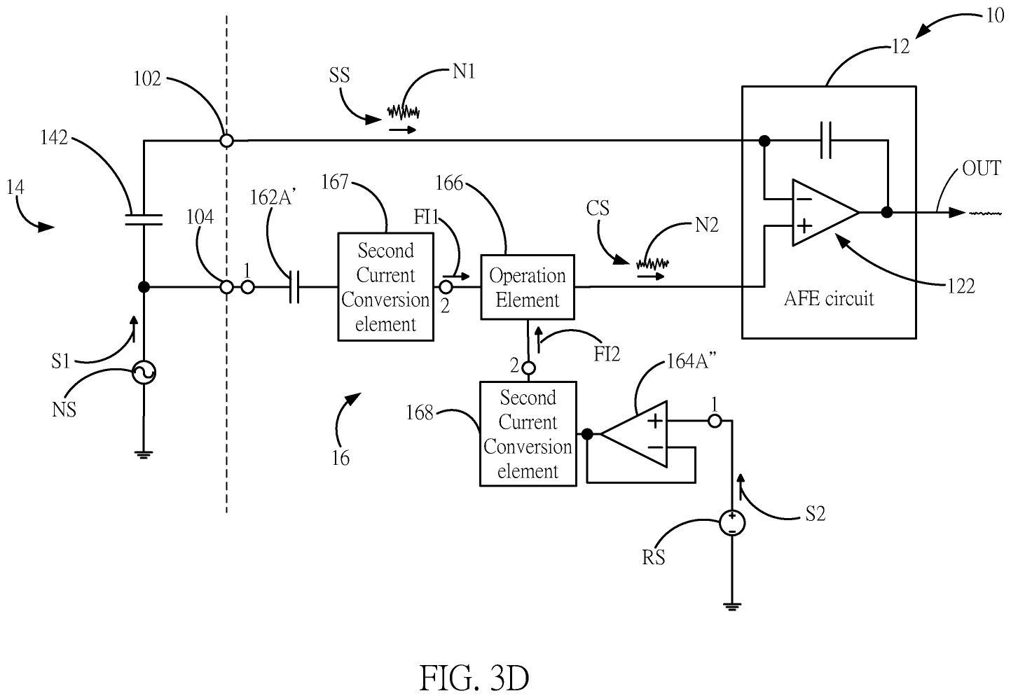

FIG. 3A shows a schematic diagram of signal transmission of the sensing device according to the second embodiment of the present application. As shown in the figure, an exemplary embodiment of the first filtering element 162 is a first high-pass filtering element 162A and an exemplary embodiment of the second filtering element 164 is a second low-pass filtering element 164A. The cutoff frequency of the first high-pass filtering element 162A is greater than the cutoff frequency of the second low-pass filtering element 164A. For example, the cutoff frequency of the first high-pass filtering element 162A is 10 MHz, meaning that the signals below 10 MHz will be cut off. The cutoff frequency of the second low-pass filtering element 164A is 1 KHz, meaning that the signals above 1 KHz will be cut off. According to the present embodiment, the noise compensation signal CS generated according to the first filtered signal FS1 and the second filtered signal FS2 is a high-frequency noise. Thereby, the high-frequency noise in the sensing signal SS may be eliminated. In addition, by using the noise compensation signal CS, the characteristics of the operating voltage of the AFE circuit 12 may be maintained.

FIG. 3B shows a schematic diagram of signal transmission of the sensing device according to the third embodiment of the present application. As shown in the figure, an embodiment of the first high-pass filtering element 162A is a filtering capacitor 162A′; an embodiment of the second low-pass filtering element 164A is a resistor 164A′. Thereby, a first terminal of the filtering capacitor 162A′ is coupled between the capacitive sensing device 142 and the first reference power source NS. A second terminal of the filtering capacitor 162A′ is coupled to the operation element 166. A first terminal of the resistor 164A′ is coupled to the second reference power source RS for receiving the analog reference signal S2. A second terminal of the resistor 164A′ is coupled to the operation element 166. According to an exemplary embodiment, the operation element 166 may be coupled to the second terminal of the filtering capacitor 162A′ and the second terminal of the resistor 164A′. Then the equivalent circuit seen from the second reference power source RS to the operation element 166 is a high-pass filtering element. The filtering method has been disclosed in the embodiments of FIG. 2 and FIG. 3A. Hence, the details will not be described again.

FIG. 3C shows a schematic diagram of signal transmission of the sensing device according to the fourth embodiment of the present application. As shown in the figure, an embodiment of the second low-pass filtering element 164A is an operational amplifier 164A″. A positive input of the operational amplifier 164A″ is coupled to the analog reference signal S2, which is equivalent to coupling the first terminal of the second low-pass filtering element 164A to the second reference power source RS for receiving the analog reference signal S2. A negative input of the operational amplifier 164A″ is coupled to an output of the operational amplifier 164A″. By shorting the negative input and the output, the operational amplifier 164A″ acts as a buffer. In addition, when the operational amplifier 164A″ acts as a buffer by shorting the negative input and the output, the bandwidth may be adjusted and making it a low-pass filtering element equivalently. Nonetheless, the present application is not limited to the embodiment. The bandwidth of the operational amplifier 164A″ may be further adjusted to form a high-pass filtering element equivalently.

FIG. 3D shows a schematic diagram of signal transmission of the sensing device according to the fifth embodiment of the present application. As shown in the figure, the difference between FIG. 3C and FIG. 3D is that the embodiment in FIG. 3D further includes a first current converter 167 and a second current converter 168. Thereby, the first high-pass filtering element 162A may generate a first filtered current FI1, which is different from the first filtered signal FS1, correspondingly by using the filtering capacitor 162A′ and the first current converter 167. Likewise, the second low-pass filtering element 164A may generate a second filtered current FI2, which is different from the second filtered signal FS2, correspondingly by using the operational amplifier 164A″ and the second current converter 168 instead. Similarly, after receiving the first filtered current FI1 and the second filtered current FI2, the operation element 166 generates the noise compensation signal CS according to the first filtered current FI1 and the second filtered current FI2 and transmits it to the AFE circuit 12 for compensating the sensing signal SS.

According to the above embodiment, the first filtering element 162 and the second filtering element 164 adopt the first high-pass filtering element 162A and the second low-pass filtering element 164A, respectively. In the next embodiment, the first filtering element 162 and the second filtering element 164 adopt a first bandpass filtering element 162B and a second low-pass filtering element 164A, respectively, as described in the following.

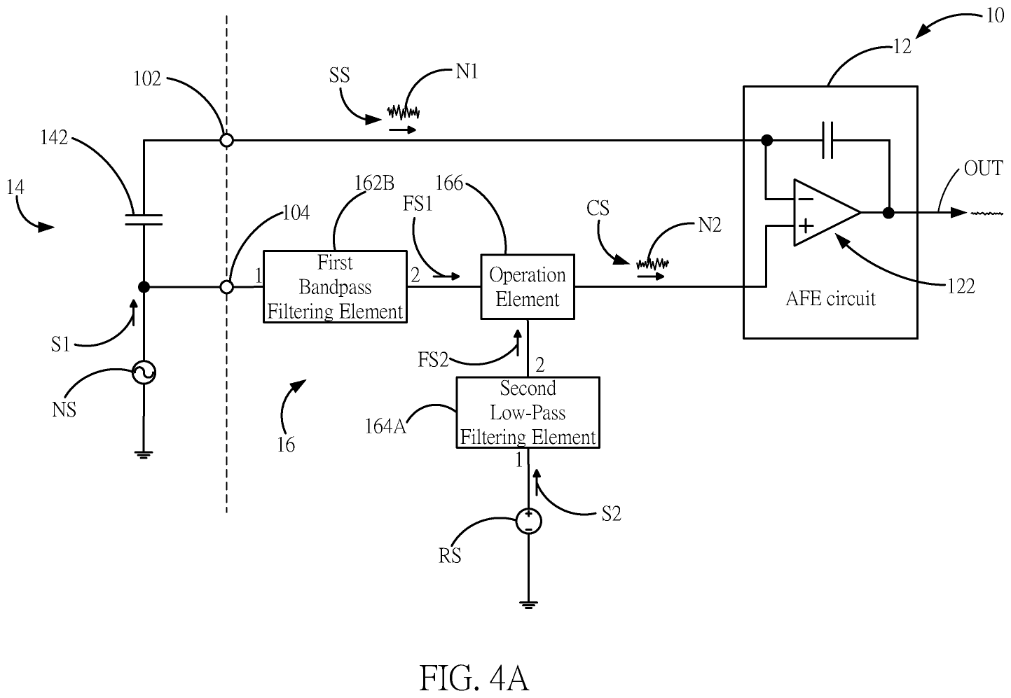

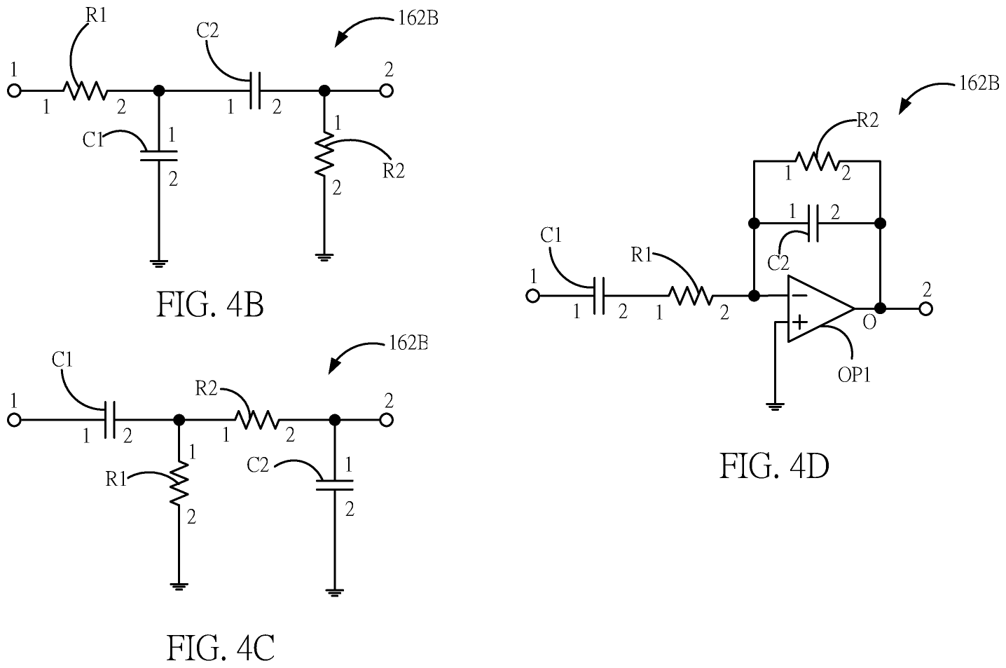

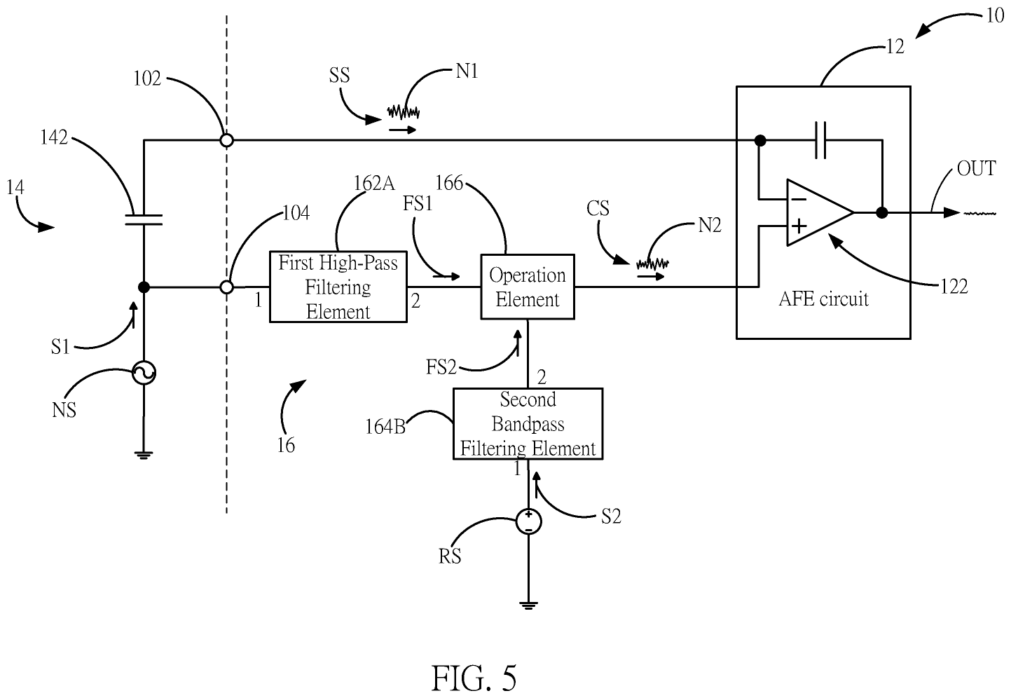

Please refer to FIG. 4A, which shows a schematic diagram of signal transmission of the sensing device according to the sixth embodiment of the present application. The difference between FIG. 3A and FIG. 4A is that the first filtering element 162 and the second filtering element 164 in FIG. 3A adopt the first high-pass filtering element 162A and the second low-pass filtering element 164A, respectively, while the first filtering element 162 and the second filtering element 164 in FIG. 4A adopt the first bandpass filtering element 162B and the second filtering element 164, respectively. In addition, the first high-pass filtering element 162A has a cutoff frequency while the first bandpass filtering element 162B has two cutoff frequencies. The two cutoff frequencies of the first bandpass filtering element 162B are greater than the cutoff frequency of the second low-pass filtering element 164A. For example, the cutoff frequencies of the first bandpass filtering element 162B are 1 MHz and 3 KHz for transmitting signals with frequencies between 1 MHz and 3 KHz. The cutoff frequency of the second low-pass filtering element 164A is 1 KHz. Thereby, the two cutoff frequencies of the first bandpass filtering element 162B are both higher than the cutoff frequency of the second low-pass filtering element 164A. Consequently, the corresponding frequency of the noise compensation signal CS according to the present embodiment is different from that of the noise compensation signal CS according to the previous embodiment.

FIG. 4B to FIG. 4D show a first to a third schematic diagrams of the first bandpass filtering element 162B according to the present application. As shown in the figures, the first bandpass filtering element 162B includes a plurality of capacitors and a plurality of resistors, for example, a first capacitor C1, a second capacitor C2, a first resistor R1, and a second resistor R2. As shown in FIG. 4B, a first terminal of the first resistor R1 is coupled to a first terminal of the first bandpass filtering element 162B; a second terminal of the first resistor R1 is coupled to a first terminal of the first capacitor C1 and a first terminal of the second capacitor C2; a second terminal of the first capacitor C1 is coupled to the ground; a second terminal of the second capacitor C2 is coupled to a second terminal of the first bandpass filtering element 162B and a first terminal of the second resistor R1; and a second terminal of the second resistor R2 is coupled to the ground.

As shown in FIG. 4C, the first terminal of the first capacitor C1 according to the present embodiment is coupled to the first terminal of the first bandpass filtering element 162B; the second terminal of the first capacitor C1 is coupled to the first terminal of the first resistor R1 and the first terminal of the second resistor R2; the second terminal of the first capacitor C1 is coupled to the ground; the second terminal of the second resistor R2 is coupled to the second terminal of the first bandpass filtering element 162B and the first terminal of the second capacitor C2; and the second terminal of the second capacitor C2 is coupled to the ground.

As shown in FIG. 4D, according to the present embodiment, the first bandpass filtering element 162B further includes a first operational amplifier OP1. The first termina of the first capacitor C1 is coupled to the first terminal of the first bandpass filtering element 162B; the second terminal of the first capacitor C1 is coupled to the first terminal of the first resistor R1; the second terminal of the first resistor R1 is coupled to a negative input of the first operational amplifier OP1, the first terminal of the second resistor R2, and the first terminal of the second capacitor C2; the second terminal of the first bandpass filtering element 162B is coupled to an output of the first operational amplifier OP1, the second terminal of the second resistor R2, and the second terminal of the second capacitor C2; and an positive input of the first operational amplifier OP1 is coupled to the ground.

According to FIG. 4B to FIG. 4D, it is known that the first bandpass filtering element 162B may be implemented using the above three figures.

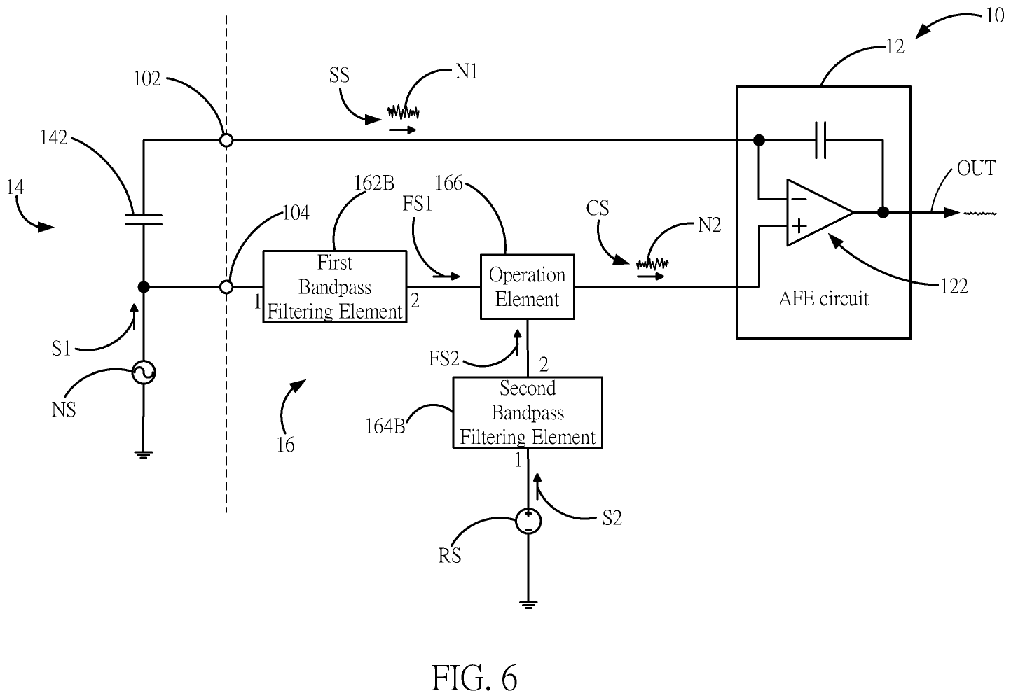

Please refer to FIG. 5, which shows a schematic diagram of signal transmission of the sensing device according to the seventh embodiment of the present application. The difference between FIG. 4A and FIG. 5 is that the first filtering element 162 and the second filtering element 164 in FIG. 4A adopt the first bandpass filtering element 162B and the second low-pass filtering element 164A, respectively, while the first filtering element 162 and the second filtering element 164 in FIG. 5 adopt the first high-pass filtering element 162A and a second bandpass filtering element 164, respectively. The first high-pass filtering element 162A according to the present embodiment is identical to the first high-pass filtering element 162A according to the above first embodiment; the second bandpass filtering element 164B according to the present embodiment is identical to the first bandpass filtering element 162B according to the above sixth embodiment, Thereby, the detailed connection of the first high-pass filtering element 162A and the second bandpass filtering element 164B according to the present embodiment will not be described again. The first high-pass filtering element 162A according to the present embodiment generates the first filtered signal FS1 according to the sensing reference signal S1; the second bandpass filtering element 164B generates the second filtered signal FS2 according to the analog reference signal S2. The operation element 166 generates the noise compensation signal CS to the AFE circuit 12 according to the first filtering element signa FS1 and the second filtered signal FS2.

FIG. 6 shows a schematic diagram of signal transmission of the sensing device according to the eighth embodiment of the present application. As shown in the figure, the first filtering element 162 and the second filtering element 164 according to the present embodiment adopt the first bandpass filtering element 162B and a second bandpass filtering element 164B instead, different from the filter high-pass filtering element 162A and a second bandpass filtering element 164B in the previous embodiment. As shown in the figure, both the first bandpass filtering element 162B and the second bandpass filtering element 164B include two cutoff frequencies, respectively. The two cutoff frequencies of the first bandpass filtering element 162B are both greater than or both smaller than the two cutoff frequencies of the second bandpass filtering element 164B. For example, the two cutoff frequencies of the first bandpass filtering element 162B are 10 MHz and 1 MHz, allowing the signals with frequencies between 10 MHz and 1 MHz to pass through. The two cutoff frequencies of the second bandpass filtering element 164B are 3 KHz and 100 Hz, allowing the signals with frequencies between 3 KHz and 100 Hz to pass through. Alternatively, the two cutoff frequencies of the second bandpass filtering element 164B are 10 MHz and 1 MHz, allowing the signals with frequencies between 10 MHz and 1 MHz to pass through. The two cutoff frequencies of the first bandpass filtering element 162B are 3 KHz and 100 Hz, allowing the signals with frequencies between 3 KHz and 100 Hz to pass through. Thereby, the operation element 166 generates the corresponding noise compensation signal CS according to the first filtered signal FS1 and the second filtered signal FS2 generated by the first bandpass filtering element 162B and the second bandpass filtering element 164B. The noise compensation signal CS corresponds to the cutoff frequencies of the first bandpass filtering element 162B and the second bandpass filtering element 164B.

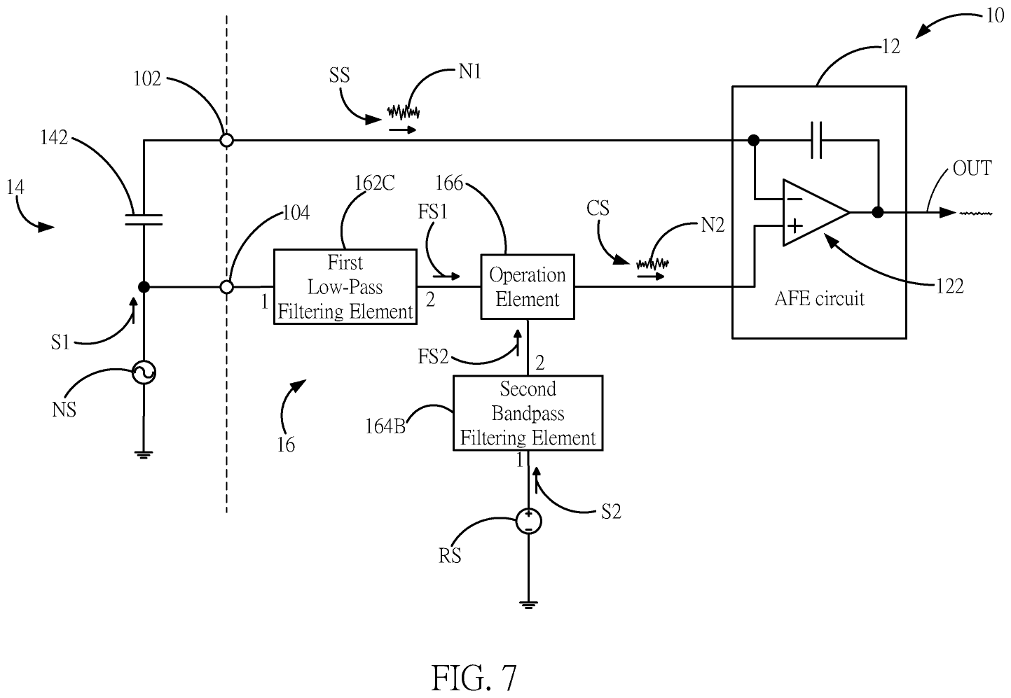

FIG. 7 shows a schematic diagram of signal transmission of the sensing device according to the ninth embodiment of the present application. The difference between FIG. 6 and FIG. 7 is that the filter 162 in FIG. 6 is the first bandpass filtering element 162B; the first filtering element 162 in FIG. 7 is a first low-pass filtering element 162C. In particular, the first low-pass filtering element 162C and the second bandpass filtering element 164B replace the first bandpass filtering element 162B and the second low-pass filtering element 164A in FIG. 4A. Thereby, the cutoff frequency of the first low-pass filtering element 162C according to the present embodiment is lower than the two cutoff frequencies of the second bandpass filtering element 164B. The method for generating the noise compensation signal CS is the same as the embodiment in FIG. 4A. Hence, the details will not be repeated.

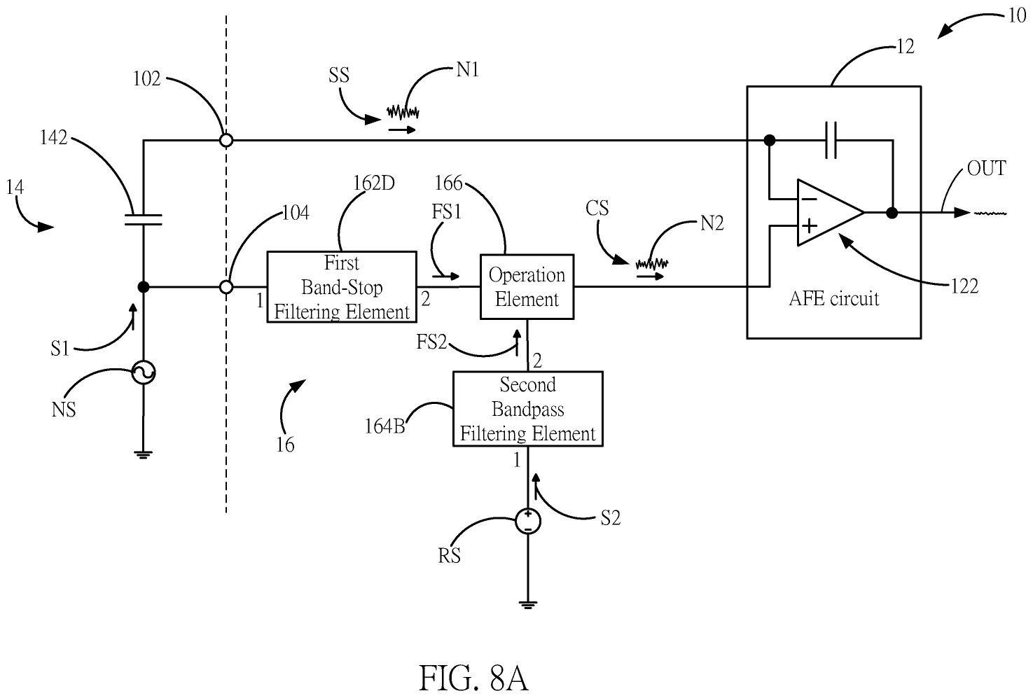

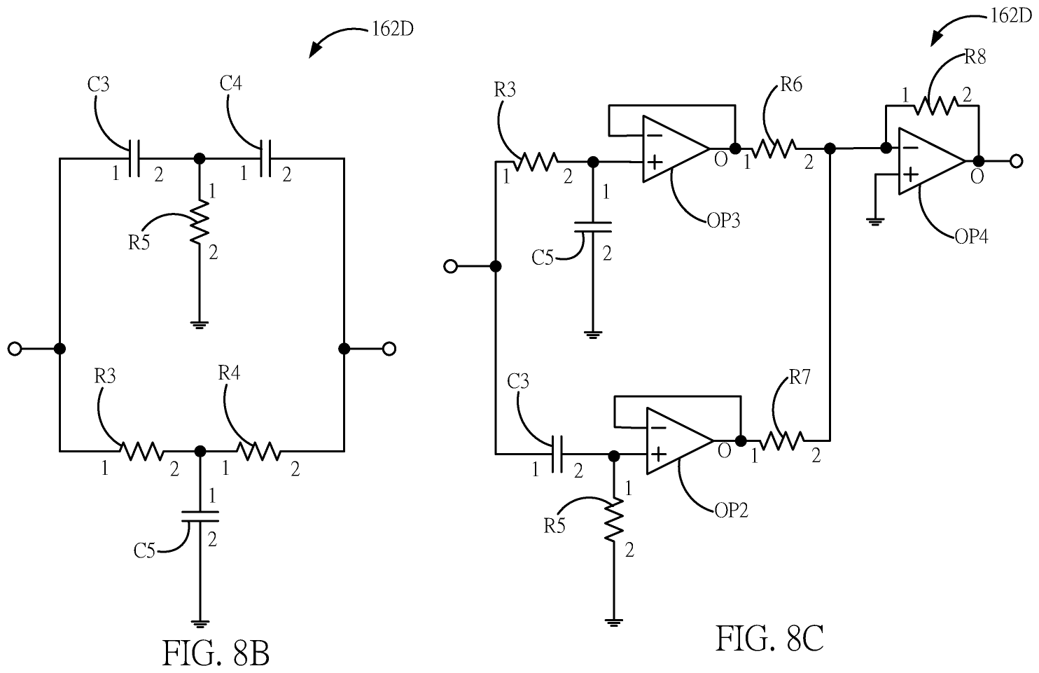

FIG. 8A shows a schematic diagram of signal transmission of the sensing device according to the tenth embodiment of the present application. The difference between FIG. 7 and FIG. 8A is that the first filtering element 162 in FIG. 7 adopts the first low-pass filtering element 162C, while the first filtering element 162 in FIG. 8A adopts a first band-stop filtering element 162D. The first band-stop filtering element 162D corresponds to two cutoff frequencies for blocking the signals between the two cutoff frequencies. Namely, the first filtered signal FS1 generated by the first band-stop filtering element 162D is a signal not between the two cutoff frequencies; the second filtered signal FS2 generated by the second bandpass filtering element 164B is between the two cutoff frequencies of the first band-stop filtering element 162D. For example, the two cutoff frequencies of the first band-stop filtering element 162D are 3 MHz and 10 KHz. Thereby, the first band-stop filtering element 162D blocks the signals between 3 MHz and 10 KHz. In other words, the frequency of the first filtered signal FS1 is greater than 3 MHz and smaller than 10 KHz. The two cutoff frequencies of the second bandpass filtering element 164B are 1 MHz and 30 KHz, meaning that the frequency of the second filtered signal FS2 is between 1 MHz and 30 KHz. In addition, the noise compensation signal CS generated by the operation element 166 corresponds to the two cutoff frequencies of the first band-stop filtering element 162D and the two cutoff frequencies of the second bandpass filtering element 164B.

Furthermore, please refer to FIG. 8B and FIG. 8C, which show a first and a second schematic diagrams of the bandpass filtering element according to the present application. The disclosed first band-stop filtering element 162D includes a plurality of resistors and a plurality of capacitors. For example, as shown in FIG. 8B, the first band-stop filtering element 162D includes a third capacitor C3, a fourth capacitor C4, a fifth capacitor C5, a third resistor R3, a fourth resistor R4, and a fifth resistor R5. A first terminal of the third capacitor C3 and a first terminal of the third resistor R3 are coupled to a first terminal of the band-stop filtering element 162D. A second terminal of the third capacitor C3 is coupled to a first terminal of the fourth capacitor C4 and a first terminal of the fifth resistor R5. A second terminal of the fifth resistor R5 is coupled to the ground. A second terminal of the third resistor R3 is coupled to a first terminal of the fourth resistor R4 and a first terminal of the fifth capacitor C5. A second terminal of the fifth capacitor C5 is coupled to the ground. A second terminal of the fourth resistor R4 and a second terminal of the fourth capacitor C4 are coupled to a second terminal of the first band-stop filtering element 162D.

As shown in FIG. 8C, the fourth resistor R4 and the fourth capacitor C4 in FIG. 8B are placed by a second operational amplifier OP2, a third operational amplifier OP3, and a fourth operational amplifier OP4. The negative inputs of the second operational amplifier OP2 and the third operational amplifier OP3 are both coupled to the outputs of the second operational amplifier OP2 and the third operational amplifier OP3. The positive inputs of the second operational amplifier OP2 and the third operational amplifier OP3 are coupled to the second terminal of the third resistor R3 and the second terminal of the third capacitor C3, respectively, and to the first terminal of the fifth capacitor C5 and the first terminal of the fifth resistor R5, respectively. Besides, the outputs of the second operational amplifier OP2 and the third operational amplifier OP3 are further coupled to a first terminal of a sixth resistor R6 and a first terminal of a seventh resistor R7, respectively. A second terminal of the sixth resistor R6 and a second terminal of the seventh resistor R7 are both coupled to a negative input of the fourth operational amplifier OP4. A positive input of the fourth operational amplifier is coupled to the ground. A first terminal and a second terminal of an eighth resistor R8 are coupled between a negative input and an output of the fourth operational amplifier OP4. The output of the fourth operational amplifier OP4 is further coupled to the second terminal of the first band-stop filtering element 162D. The rest connections are identical to the first schematic diagram of the first band-stop filtering element 162D as shown in FIG. 8B.

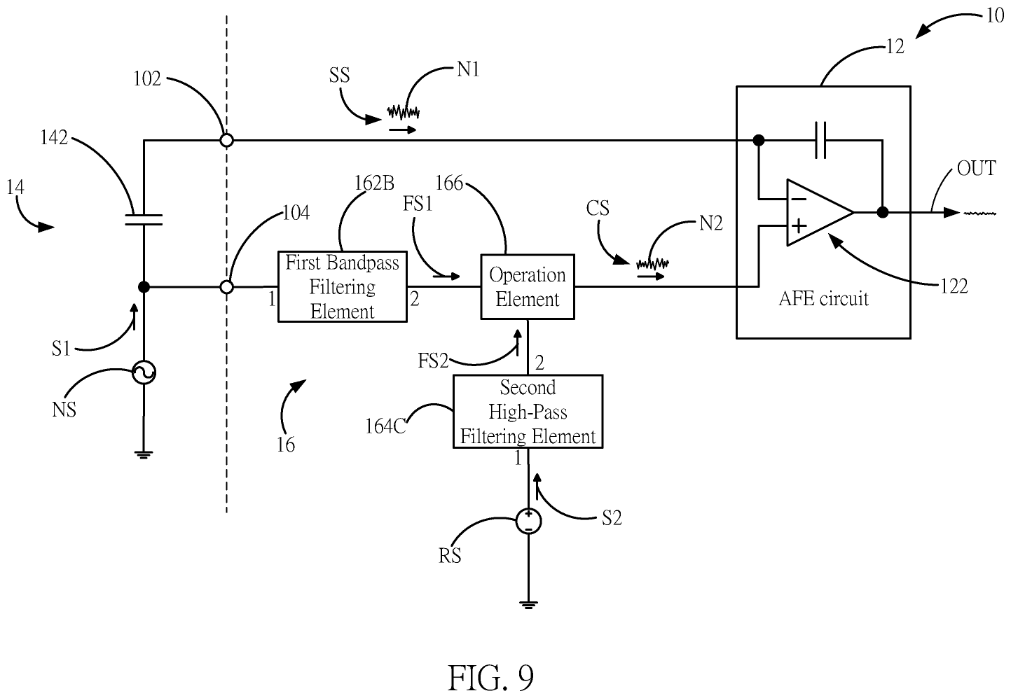

FIG. 9 shows a schematic diagram of signal transmission of the sensing device according to the eleventh embodiment of the present application. The difference between FIG. 8A and FIG. 9 is that the first filtering element 162 and the second filtering element 164 in FIG. 8A adopt the first band-stop filtering element 162D and the second bandpass filtering element 164B, while the first filtering element 162 and the second filtering element 164 in FIG. 9 adopt the first bandpass filtering element 162B and a second high-pass filtering element 164C. FIG. 9 is equivalent to exchanging the first high-pass filtering element 162A and the second bandpass filtering element 164B in FIG. 5. Hence, the details will not be repeated.

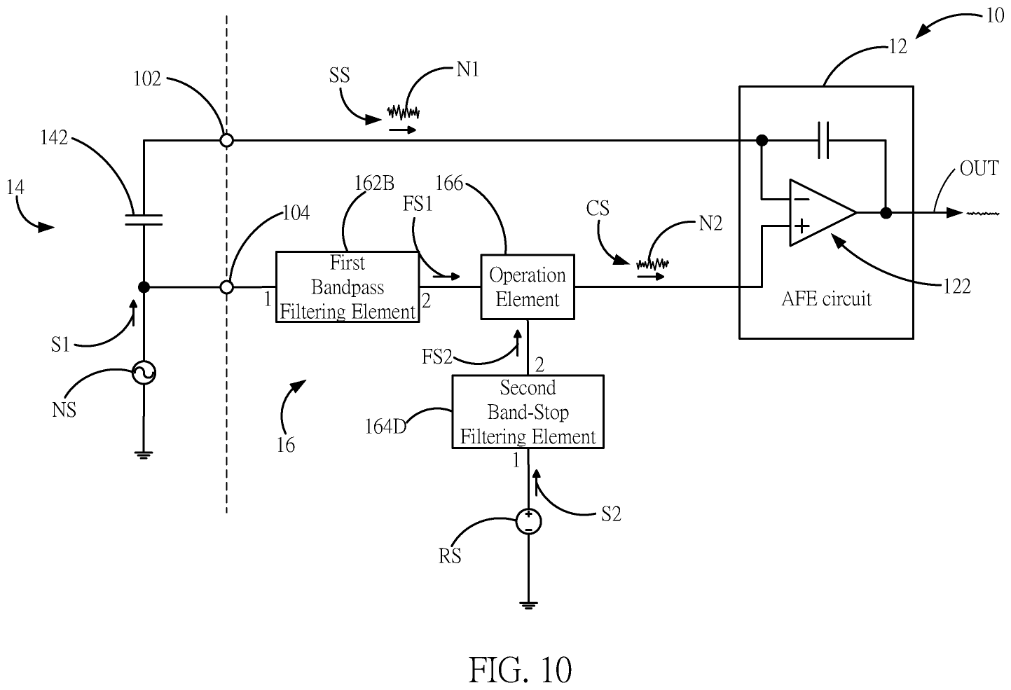

FIG. 10 shows a schematic diagram of signal transmission of the sensing device according to the twelfth embodiment of the present application. The difference between FIG. 9 and FIG. 10 is that the second filtering element 164 in FIG. 9 is the second high-pass filtering element 164C while the second filtering element 164 in FIG. 10 is a second band-stop filtering element 164D. FIG. 10 is equivalent to exchanging the first band-stop filtering element 162D and the second bandpass filtering element 164B in FIG. 8A. Hence, the details will not be repeated.

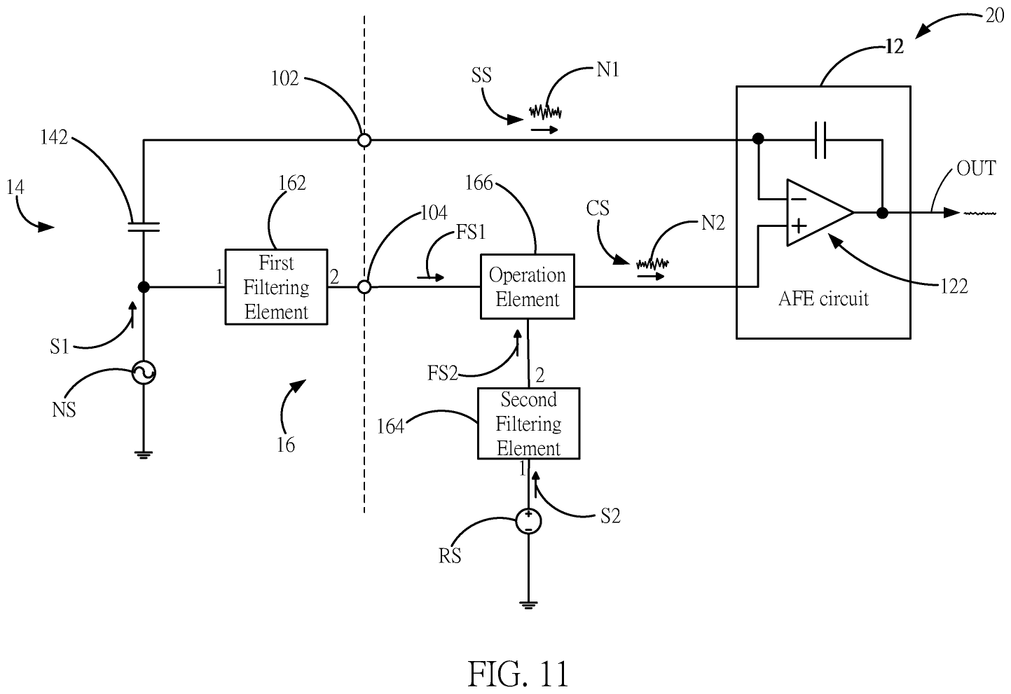

In the previous embodiments, the first terminal of the first filtering element 162 is coupled to the non-sensing terminal 104. That is to say, the first filtering element 162 is disposed in the internal circuit of the sensing device 10. Nonetheless, the present application is not limited to the embodiments. As shown in FIG. 11, the invention further discloses another sensing device 20 with a first filtering element 162 disposed in the external circuit of the sensing device 20. Namely, the sensing device 20 is coupled to the sensing circuit 14 and the first filtering element 162. The first terminal of the first filtering element 162 is coupled directly between the capacitive sensing device of the sensing circuit 14 and the first reference power source NS. In addition, the capacitive sensing device 142 is further coupled to the sensing termina 102 for coupling to the AFE circuit 12. The second terminal of the first filtering element 162 is coupled to the non-sensing terminal 104 of the sensing device 20 for coupling to the operation element 166 and proving the noise compensation signal CS to the AFE circuit 12, as described in the following.

Please refer again to FIG. 11. The first filtering element 162 according to the present embodiment is disposed in the external circuit of the sensing device 20 while the second filtering element 164 is still disposed in the internal circuit of the sensing device 20. Thereby, the noise compensation circuit 16 according to the present embodiment includes the second filtering element 164 and the operation element 166. The first filtering element 162 generates the first filtered signal FS1 according to the sensing reference signal S1 and inputs the first filtered signal FS1 to the operation element 166 from the non-sensing terminal 104. The second filtered signal FS2 generated by the second filtering element 164 according to the analog reference signal S2 is still transmitted to the operation element 166 from the internal circuit of the sensing device 20. Thereby, the operation element 166 generates the noise compensation signal CS to the AFE circuit 12 according to the first filtered signal FS1 and the second filtered signal FS2 so that the AFE circuit 12 may compensate the sensing signal SS from the sensing circuit 14 according to the noise compensation signal CS. Consequently, the output signal OUT will be generated with a flatter and smoother waveform.

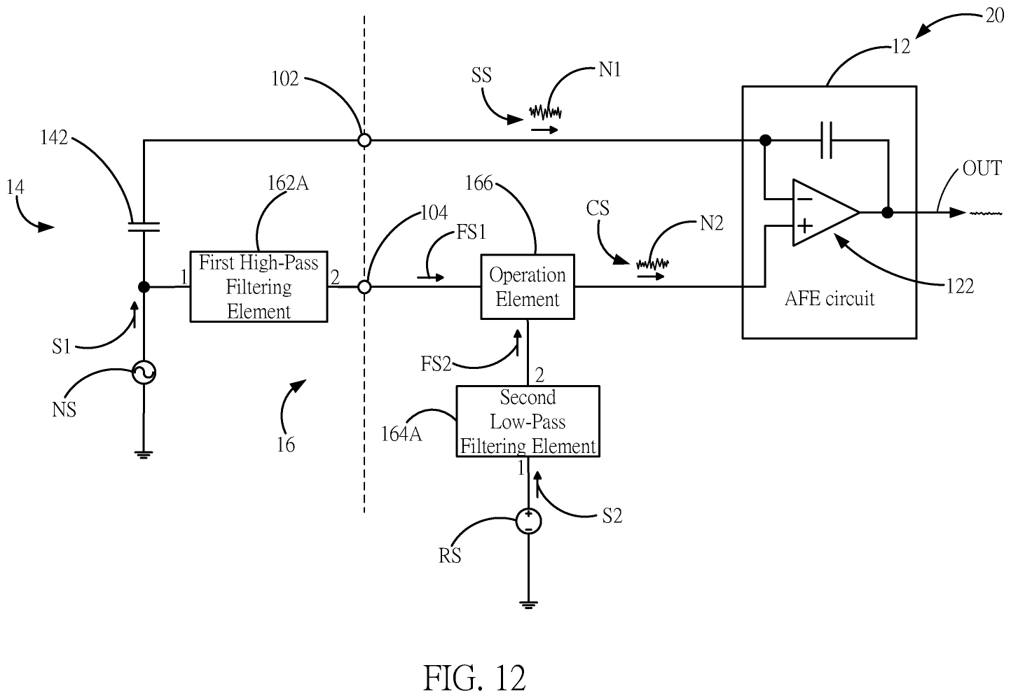

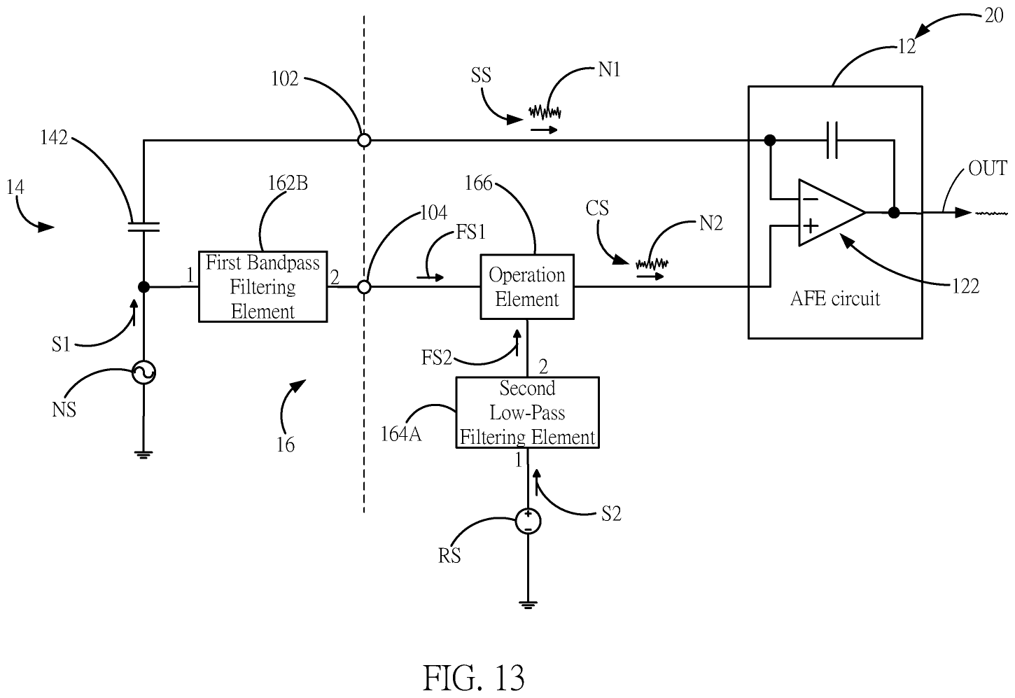

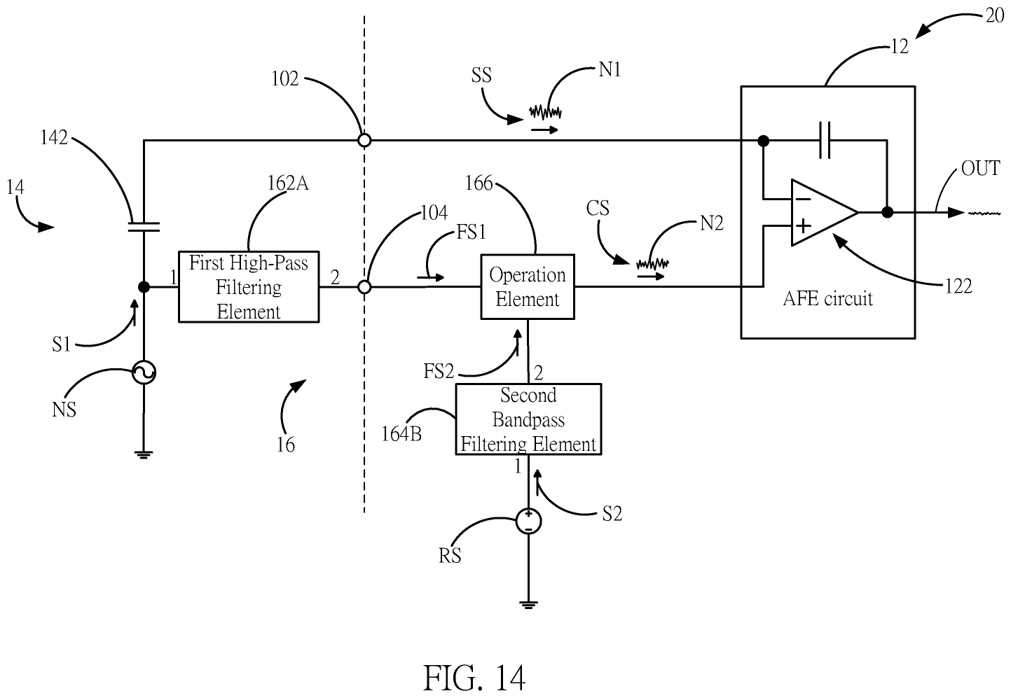

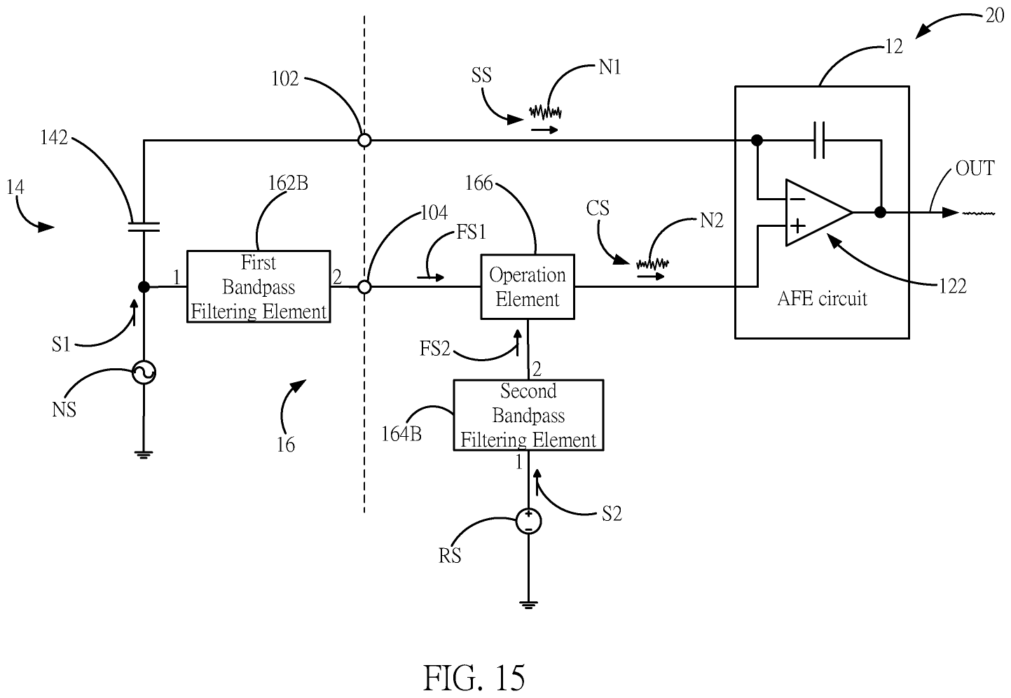

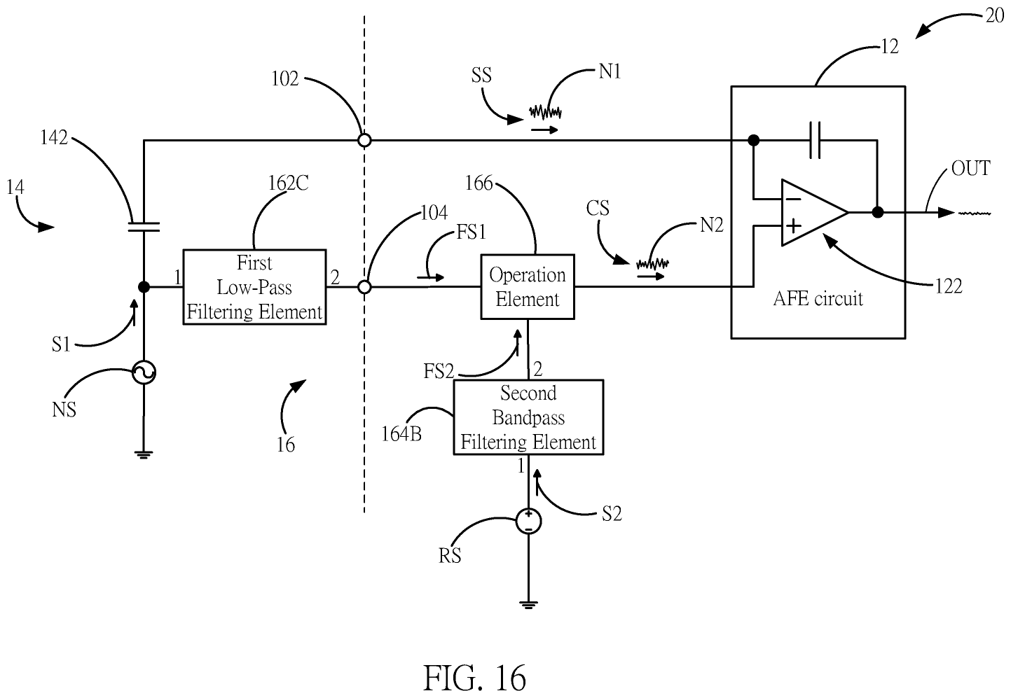

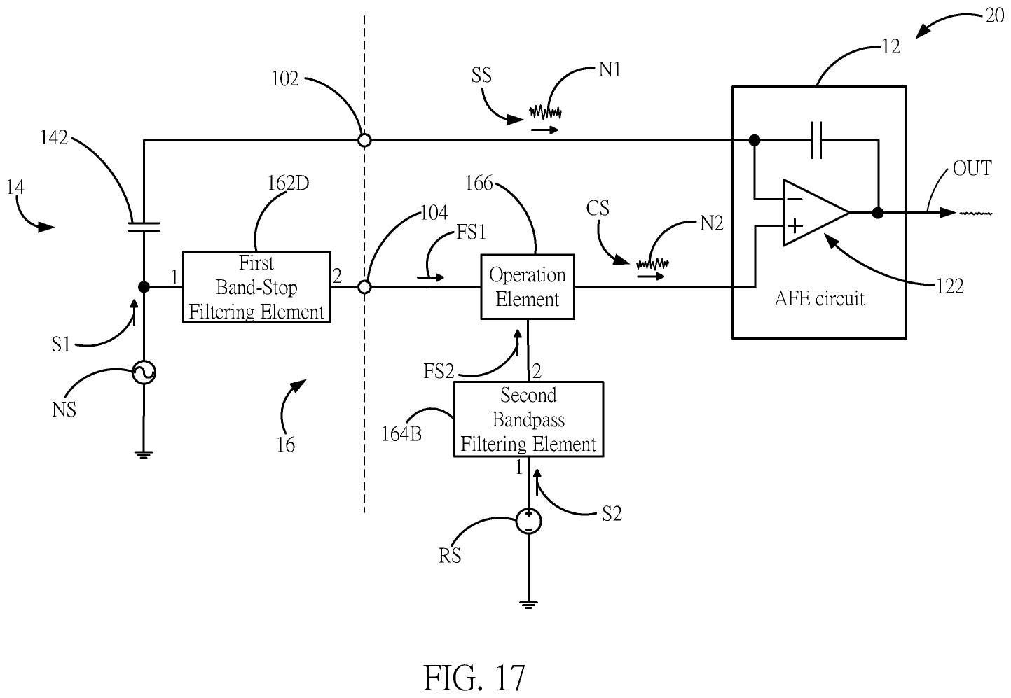

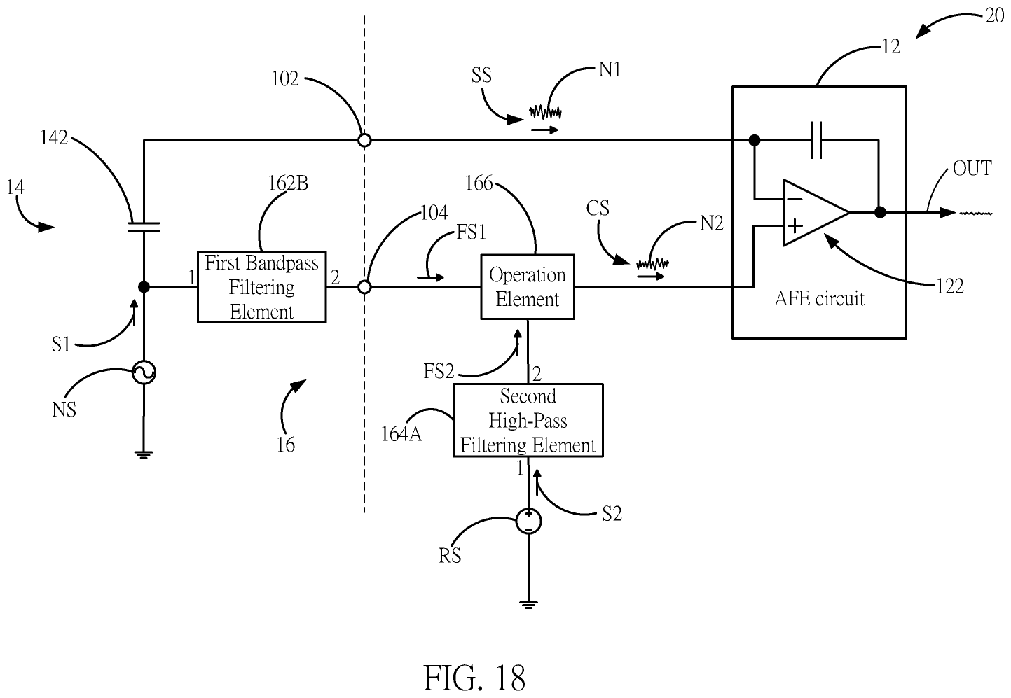

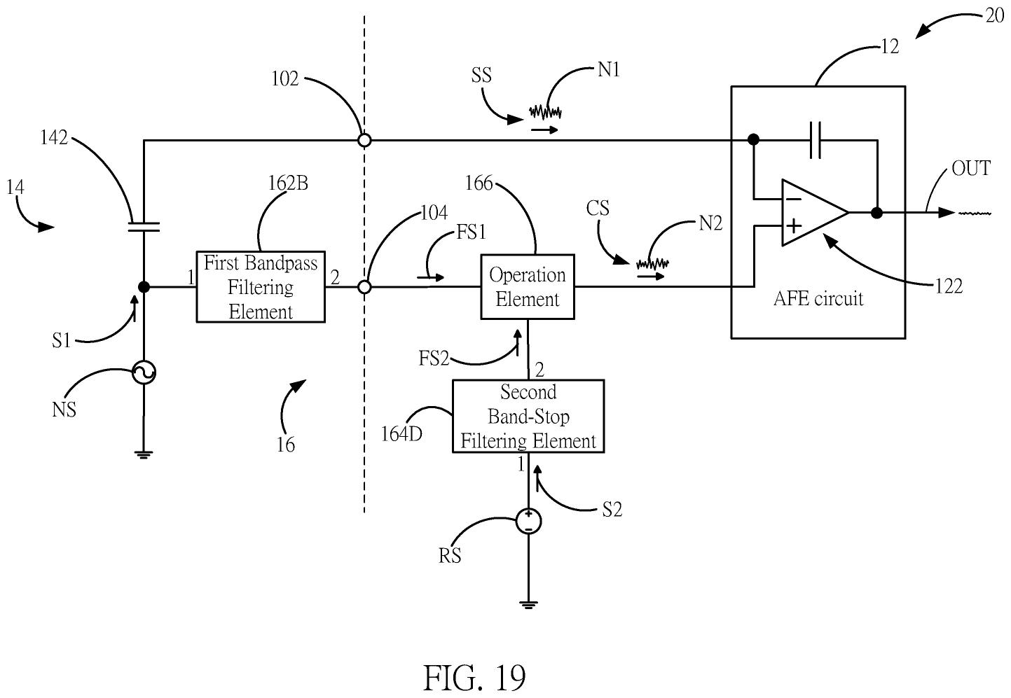

FIG. 12 to FIG. 19 shows schematic diagrams of signal transmission of the sensing device according to the fourteenth to the twenty-first embodiments of the present application. The figures show signal transmission of the sensing device 20 in FIG. 11. Namely, the figures show signal transmission of the first filtering element 162 and the second filtering element 164 in FIG. 11 by changing the location of the first filtering element 162 to the external circuit of the sensing device 10 in FIG. 2. FIG. 3A, FIG. 4A, FIG. 5, FIG. 6, FIG. 7, FIG. 8A, FIG. 9, and FIG. 10 are similar to FIGS. 12 to 19. The difference is only the location of the first filtering element 162. Hence, the details will not be repeated. Likewise, the sensing device 20 may generate the corresponding noise compensation signal CS by using the first filtering element 162, the second filtering element 164, and the operation element 166 for compensating the first noise N1 in the sensing signal SS received by the AFE circuit 12, maintaining the characteristics of the operating voltage of the AFE circuit 12, as well as improving the signal-to-noise ratio of the sensing circuit 14.

To sum up, the present application provides a sensing device, which comprises an AFE circuit, a sensing circuit, and a noise compensation circuit. The noise compensation circuit includes a first filtering element, a second filtering element, and an operation element. The first filtering element is coupled between the sensing circuit and a corresponding sensing reference signal; the second filtering element is coupled to an analog reference signal corresponding to the AFE circuit. Thereby, a filter signal and a second filtered signal will be generated to the operation element, respectively. The operation element generates a noise compensation signal to the AFE circuit according to the first filtered signal and the second filtered signal. The AFE circuit compensates the sensing signal transmitted to the AFE circuit by the sensing circuit according to the noise compensation signal for reducing a noise in the sensing signal. Consequently, the waveform of the output signal from the AFE circuit may be flatter and smoother; the characteristics of the operating voltage of the AFE circuit may be maintained; and the signal-to-noise ratio of the sensing circuit may be improved.

Accordingly, the present application conforms to the legal requirements owing to its novelty, nonobviousness, and utility. However, the foregoing description is only embodiments of the present application, not used to limit the scope and range of the present application. Those equivalent changes or modifications made according to the shape, structure, feature, or spirit described in the claims of the present application are included in the appended claims of the present application.

1. A sensing device, comprising:
a sensing circuit, generating a sensing signal;
an analog-front-end (AFE) circuit, coupled to said sensing circuit and receiving said sensing signal; and
a noise compensation circuit, coupled to said sensing circuit and said AFE circuit, including a first filtering element, a second filtering element, and an operation element, said first filtering element generating a first filtered signal according to a corresponding sensing reference signal of said sensing signal, said second filtering element generating a second filtered signal according to an analog reference signal, said operation element generating a noise compensation signal according to said first filtered signal and said second filtered signal, and said AFE circuit compensating said sensing signal according to said noise compensation signal.

2. The sensing device of claim 1, wherein said first filtering element and said second filtering element have different cutoff frequencies.

3. The sensing device of claim 1, wherein said a first terminal of said first filtering element is coupled between said sensing circuit and a first reference power supply; said first reference power supply supplies said sensing reference signal to said sensing circuit; a second terminal of said first filtering element is coupled to said operation element; a first terminal of said second filtering element is coupled to a second reference voltage source; said second reference voltage source supplies said analog reference signal to said noise compensation circuit; a second terminal of said second filtering element is coupled to said operation element; and said operation element is further coupled to said AFE circuit.

4. The sensing device of claim 3, further comprising a sensing terminal and a non-sensing terminal, said sensing circuit coupled to said AFE circuit via said sensing terminal, and said first terminal of said first filtering element coupled between said sensing circuit and said sensing reference signal via said non-sensing terminal.

5. The sensing device of claim 1, wherein said analog reference signal corresponds to an operating voltage of said AFE circuit.

6. The sensing device of claim 1, wherein said first filtering element is a first high-pass filtering element and said second filtering element is a second low-pass filtering element; and a first cutoff frequency of said first filtering element is greater than a second cutoff frequency of said second filtering element.

7. The sensing device of claim 1, wherein said first filtering element is a first low-pass filtering element and said second filtering element is a second high-pass filtering element; and a first cutoff frequency of said first filtering element is smaller than a second cutoff frequency of said second filtering element.

8. The sensing device of claim 1, wherein said first filtering element and said second filtering element are bandpass filtering elements; and a first cutoff frequency and a second cutoff frequency of said first filtering element are greater than or smaller than a third cutoff frequency and a fourth cutoff frequency of said second filtering element.

9. The sensing device of claim 1, wherein said first filtering element is a first bandpass filtering element and said second filtering element is a second low-pass filtering element; and a first cutoff frequency and a second cutoff frequency of said first filtering element are greater than a third cutoff frequency of said second filtering element.

10. The sensing device of claim 1, wherein said first filtering element is a first bandpass filtering element and said second filtering element is a second high-pass filtering element; and a first cutoff frequency and a second cutoff frequency of said first filtering element are smaller than a third cutoff frequency of said second filtering element.

11. The sensing device of claim 1, wherein said first filtering element is a first band-stop filtering element and said second filtering element is a second bandpass filtering element; a first cutoff frequency of said first filtering element is smaller than a third cutoff frequency of said second filtering element; and a second cutoff frequency of said first filtering element is greater than a fourth cutoff frequency of said second filtering element.

12. The sensing device of claim 1, wherein said first filtering element is a first bandpass filtering element and said second filtering element is a second band-stop filtering element; a first cutoff frequency of said first filtering element is greater than a third cutoff frequency of said second filtering element; and a second cutoff frequency of said first filtering element is smaller than a fourth cutoff frequency of said second filtering element.

13. The sensing device of claim 1, wherein said AFE circuit includes an amplifier circuit; said amplifier circuit receivers said sensing signal and said noise compensation signal and compensates said sensing signal according to said noise compensation signal for reducing a noise in said sensing signal.

14. A sensing device, coupled to a sensing circuit and a first filtering element, said sensing circuit generating a sensing signal, said first filtering element coupled to said sensing circuit and generating a first filtered signal according to a corresponding sensing reference signal of said sensing signal, and comprising:
an analog-front-end (AFE) circuit, coupled to said sensing circuit and receiving said sensing signal;
a second filtering element, generating a second filtered signal according to an analog reference signal corresponding to said AFE circuit; and
an operation element, coupled to said first filtering element, said second filtering element, and said AFE circuit, generating a noise compensation signal according to said first filtered signal and said second filtered signal, and said AFE circuit compensating said sensing signal according to said noise compensation signal.

15. The sensing device of claim 14, wherein said first filtering element and said second filtering element have different cutoff frequencies.

16. The sensing device of claim 14, wherein said a first terminal of said first filtering element is coupled between said sensing circuit and a first reference power supply; said first reference power supply supplies said sensing reference signal to said sensing circuit; a second terminal of said first filtering element is coupled to said operation element; a first terminal of said second filtering element is coupled to a second reference voltage source; said second reference voltage source supplies said analog reference signal to said second filtering element; a second terminal of said second filtering element is coupled to said operation element; and said operation element is further coupled to said AFE circuit.

17. The sensing device of claim 16, further comprising a sensing terminal and a non-sensing terminal, said sensing circuit coupled to said AFE circuit via said sensing terminal, and said second terminal of said first filtering element coupled to said operation element via said non-sensing terminal.

18. The sensing device of claim 14, wherein said analog reference signal corresponds to an operating voltage of said AFE circuit.

19. The sensing device of claim 14, wherein said first filtering element is a first high-pass filtering element and said second filtering element is a second low-pass filtering element; and a first cutoff frequency of said first filtering element is greater than a second cutoff frequency of said second filtering element.

20. The sensing device of claim 14, wherein said first filtering element is a first low-pass filtering element and said second filtering element is a second high-pass filtering element; and a first cutoff frequency of said first filtering element is smaller than a second cutoff frequency of said second filtering element.

21. The sensing device of claim 14, wherein said first filtering element and said second filtering element are bandpass filtering elements; and a first cutoff frequency and a second cutoff frequency of said first filtering element are greater than or smaller than a third cutoff frequency and a fourth cutoff frequency of said second filtering element.

22. The sensing device of claim 14, wherein said first filtering element is a first bandpass filtering element and said second filtering element is a second low-pass filtering element; and a first cutoff frequency and a second cutoff frequency of said first filtering element are greater than a third cutoff frequency of said second filtering element.

23. The sensing device of claim 14, wherein said first filtering element is a first bandpass filtering element and said second filtering element is a second high-pass filtering element; and a first cutoff frequency and a second cutoff frequency of said first filtering element are smaller than a third cutoff frequency of said second filtering element.

24. The sensing device of claim 14, wherein said first filtering element is a first band-stop filtering element and said second filtering element is a second bandpass filtering element; a first cutoff frequency of said first filtering element is smaller than a third cutoff frequency of said second filtering element; and a second cutoff frequency of said first filtering element is greater than a fourth cutoff frequency of said second filtering element.

25. The sensing device of claim 14, wherein said first filtering element is a first bandpass filtering element and said second filtering element is a second band-stop filtering element; a first cutoff frequency of said first filtering element is greater than a third cutoff frequency of said second filtering element; and a second cutoff frequency of said first filtering element is smaller than a fourth cutoff frequency of said second filtering element.

26. The sensing device of claim 14, wherein said AFE circuit includes an amplifier circuit; said amplifier circuit receivers said sensing signal and said noise compensation signal and compensates said sensing signal according to said noise compensation signal for reducing a noise in said sensing signal.
